(19) United States
(12) Patent Application Publication
(10) Pub. No.: US 2019/0213694 A1
(43) Pub. Date: Jul. 11, 2019

(54) METHOD AND APPARATUS FOR DETECTING ABNORMAL TRAFFIC BASED ON CONVOLUTIONAL AUTOENCODER

(71) Applicant: KOREA ELECTRIC POWER CORPORATION, Naju-si (KR)

(72) Inventors: Jung Il LEE, Daejeon (KR); Hee Jeong PARK, Daejeon (KR); Young Bae PARK, Daejeon (KR); Jun-Sung KIM, Daejeon (KR)

(73) Assignee: KOREA ELECTRIC POWER CORPORATION, Naju0si (KR)

(21) Appl. No.: 16/315,474

(22) PCT Filed: Dec. 1, 2016
(86) PCT No.: PCT/KR2016/014076

§ 371 Date: Jan. 4, 2019

(30) Foreign Application Priority Data
Aug. 3, 2016 (KR) 10-2016-0098890

(51) Int. Cl. G06Q 50/06; G06Q 30/02; G01R 22/10; H02J 3/00

(52) U.S. Cl. CPC G06Q 50/06; G06Q 30/0202; H02J 2003/003; H02J 3/008; G01R 22/10

(57) ABSTRACT

A method of supporting collection of demand resources among electricity consumers in a micro grid may include: selecting a number of demand resource participating customers that are greater than or equal to a predetermined number of households and verifying electricity consumption types for the selected participating customers; calculating electricity consumption patterns and electricity consumption fluctuation rates for the customers who have passed the electricity consumption type verification; assessing potential reduction amounts for the customers who have passed the fluctuation rate calculation; checking whether the number of participating customers is greater than or equal to the predetermined number of households according to demand resource registration criteria and the sum of potential reduction amounts of participating customers satisfies a requirement for a demand reduction amount; and calculating a customer baseline load that maximizes a reduction amount of a customer using customer baseline load calculation methods when a demand resource is configured.

### TECHNICAL FIELD

The present invention relates to an apparatus and method for supporting collection of demand resources among electricity consumers in a micro grid, and more specifically, to an apparatus and method for supporting collection of demand resources among electricity consumers in a micro grid, which allow support for recruitment of an electricity consumer employable as a demand resource by utilizing electricity consumer data.

### BACKGROUND ART

In general, a micro grid is a kind of smart grid system and refers to a small power system capable of self-sufficiency of electric energy in a small area, or a small-scale power grid that is established with a distributed power source, a renewable energy source, and an energy storage device in a predetermined area and is capable of operating in conjunction with, or independently of, an external large-scale power grid.

Meanwhile, a Negawatt market (or a demand resource trading market) has been introduced as part of a new energy industry encouraging policy. The demand resource trading market refers to a market where extra electricity that is not generated by a power plant but is saved can be sold back. Through the Negawatt market, institutions, such as factories, large retailers, and buildings, and general electric power consumers, which have made a contract with a demand management operator (i.e., power broker), may be able to sell back as much electricity as they have saved by consuming less electricity than before.

In this case, the demand management operators may encourage customers (demand resources), who are autonomously recruited by the demand management operators, to save electricity, the amount of power reduction gathered in such a manner may be sold through the “demand response resource electric power trading system (demand resource trading market),” which is a computerized trading system operated by the Korea Power Exchange, and the operators and the customers (demand resources) share the profits from the sales.

Therefore, the demand management operators should be able to newly find or recruit customers (demand resources) (i.e., customers who are highly likely to carry out demand reduction), and there is a need for an apparatus and method capable of supporting such recruitment.

The prior art of the present invention is disclosed in Korean Laid-Open Patent Publication No. 10-2014-0119342 (“Method of applying response mobility load to demand response market for electric power and system for management electric charging of mobility load,” published on Oct. 10, 2014).

### DISCLOSURE

### Technical Problem

According to one aspect of the present invention, the present invention is devised to solving the aforementioned problems and is directed to providing an apparatus and method for supporting collection of demand resources among electricity consumers in a micro grid, which allow support for recruitment of an electricity consumer employable as a demand resource by using electricity consumer data.

### Technical Solution

One aspect of the present invention provides an apparatus for supporting collection of demand resources among electricity consumers in a micro grid, the apparatus including an electricity consumption type verification unit configured to measure an accuracy of reduction amount assessment for a customer, who participates as a demand resource among electricity consumers, to thereby verify whether the customer is employable as a demand resource customer; an electricity consumption pattern estimation unit configured to estimate an electricity consumption pattern of the customer; an electricity consumption fluctuation rate calculating unit configured to calculate an electricity consumption fluctuation rate of the customer using the electricity consumption pattern; a potential reduction amount assessment unit configured to a potential reduction amount of the customer using the electricity consumption pattern; a demand resource registration criteria check unit configured to check whether the sum of potential reduction amounts of the customers for whom the assessment is completed by the potential reduction amount assessment unit satisfies demand resource registration criteria; a customer baseline load calculation unit configured to calculate, for the customers satisfying the demand resource registration criteria, customer baseline loads by which project profitability is maximized; and a customer baseline load calculation result output unit configured to output a result of the calculation by the customer baseline load calculation unit using a chart and a details table.

The electricity consumption type verification unit may calculate an error between a customer baseline load and an actual electricity usage amount consumed during a verification target period by using a relative root mean squared error (RRMSE) technique so as to determine, on the basis of an RRMSE result, whether the customer is employable as a demand resource customer.

The electricity consumption type verification unit may calculate daily electricity usage amounts by extracting electricity usage amounts at predetermined time intervals during a predetermined time period for a predetermined number of weekdays from predetermined days prior to a demand resource customer registration date input by a user, calculate an average daily electricity usage amount by averaging the daily electricity usage amounts, calculate daily electricity usage rates for the predetermined number of weekdays, exclude a predetermined number of days in a descending order of the average daily electricity usage rate, calculate, for the remaining weekdays after excluding the predetermined number of days from the predetermined number of weekdays, customer baseline loads at each time period during a predetermined period of time, and calculate the RRMSE between the customer baseline load and the actual electricity usage amount.

The electricity consumption pattern estimation unit may estimate maximum/minimum/average monthly electricity consumption patterns of the customer using customer's weekday electricity usage amount data for the last predetermined number of years.

The electricity consumption pattern estimation unit may extract, from electricity usage amount data for the last predetermined number of years, electricity usage amount data at predetermined time intervals for a predetermined number of weekdays, calculate monthly electricity consumption patterns using the extracted electricity usage amount data, and estimate a maximum monthly electricity consumption pattern, a minimum monthly electricity consumption pattern, and an average monthly electricity consumption pattern from the calculated monthly electricity consumption patterns.

The potential reduction amount assessment unit may calculate monthly potential reduction amount which is savable on average for each time period in each month for the last predetermined number of years, calculate representative monthly potential reduction amount by weighted averaging values of every three monthly potential reduction amounts of the same month, and finally calculate the customer's potential reduction amount by applying a weight in consideration of seasonal characteristics of each month.

The demand resource registration criteria may include the number of demand resource customers that is greater than or equal to the predetermined number of households and the sum of potential reduction amounts of demand resource customers that is greater than or equal to several tens of megawatts and less than or equal to several hundreds of megawatts.

The customer baseline load calculation unit may provide customer baseline load calculation methods for at least four cases (Case 1 to Case 4), and in connection with a first case (Case 1: Max(4/5)), the customer baseline load calculation unit may calculate an average electricity usage amount of a time period during the last predetermined number of weekdays prior to a day of customer baseline load calculation, extract a predetermined maximum number of similar days from the last predetermined number of reference days prior to the day of customer baseline load calculation, and calculate the customer baseline load by averaging electricity usage amounts of the predetermined maximum number of similar days.

In connection with a second case (Case 2: Max((4/5)+SAA) among the four cases, the customer baseline load calculation unit may calculate a customer baseline load in the same method as the first case, and in order to reflect an electricity usage type according to a temperature error between a similar day and the day of customer baseline load calculation, the customer baseline load calculation unit may obtain an average electricity usage amount for a predetermined period of time before a predetermined time of the day of customer baseline load calculation, subtract an average electricity usage amount for the same period of a similar day from the obtained average electricity usage amount, and calculate an adjusted customer baseline load by adding a subtraction result to the previously calculated customer baseline load.

In connection with a third case (Case 3: Mid(6/10)) among the four cases, the customer baseline load calculation unit may calculate an average electricity usage amount for a predetermined time period during the previously predetermined number of weekdays prior to the day of customer baseline load calculation, extract similar days from the predetermined number of reference days prior to the day of customer baseline load calculation, excluding days with a maximum electricity usage amount and days with a minimum electricity usage amount, and calculate the customer baseline load by averaging electricity usage amounts of the similar days.

In connection with a fourth case (Case 4: Mid(6/10)+SAA) among the four cases, the customer baseline load calculation unit may calculate a customer baseline load in the same method as the third case, and in order to reflect an electricity usage type according to a temperature error between a similar day and the day of customer baseline load calculation, the customer baseline load calculation unit may obtain an average electricity usage amount for a predetermined period of time before a predetermined time of the day of customer baseline load calculation, subtract an average electricity usage amount for the same period of a similar day from the obtained average electricity usage amount, and calculate an adjusted customer baseline load by adding a subtraction result to the previously calculated customer baseline load.

Another aspect of the present invention provides a method of supporting collection of demand resources among electricity consumers in a micro grid, the method including selecting, by an electricity consumption type verification unit, a number of demand resource participating customers that are greater than or equal to a predetermined number of households and verifying electricity consumption types for the selected participating customers; calculating, by an electricity consumption pattern estimation unit and an electricity consumption fluctuation rate calculation unit, electricity consumption patterns and electricity consumption fluctuation rates, respectively, for the customers who have passed the electricity consumption type verification; assessing, by a potential reduction amount assessment unit, potential reduction amounts for the customers who have passed the electricity consumption fluctuation rate calculation; checking, by a demand resource registration criteria check unit, whether the number of participating customers is greater than or equal to the predetermined number of households according to demand resource registration criteria and the sum of potential reduction amounts of participating customers satisfies a requirement for a demand reduction amount; and calculating, by a customer baseline load calculation unit, a customer baseline load that maximizes a reduction amount of a customer using one or more customer baseline load calculation methods that is selectable for each customer satisfying the demand resource registration criteria when a demand resource is configured.

In order to verify the electricity consumption type, the electricity consumption type verification unit may calculate an error between a customer baseline load and an actual electricity usage amount consumed during a verification target period using an RRMSE technique, and exclude a customer with an RRMSE greater than a predetermined baseline value from demand resource participating customers.

After the electricity consumption fluctuation rates are calculated, a customer with the electricity consumption fluctuation rate that is less than a predetermined baseline value may be excluded from demand resource participating customers.

The electricity consumption fluctuation rate may be used as an indicator for determining whether a demand reduction instruction is implementable by the customer, a higher electricity consumption fluctuation rate may indicate a higher rate of implementation of the demand reduction instruction, and a lower electricity consumption fluctuation rate may indicate a lower rate of implementation of the demand reduction instruction.

The potential reduction amount may be used to determine how much demand is savable by the customer, more settlement amount may be received with a small number of customers as the potential reduction amount is higher, and when the potential reduction amount is low, more customers may need to be recruited.

### Advantageous Effects

According to one aspect of the present invention, it is possible to support recruitment of electricity consumers who are employable as demand resources by utilizing electricity consumer data.

### DESCRIPTION OF DRAWINGS

FIG. 1 is an example diagram illustrating a schematic configuration of an apparatus for supporting collection of demand resources among electricity consumers in a micro grid according to one embodiment of the present invention.

FIG. 2 is a flowchart for describing a method of supporting collection of demand resources among electricity consumers in a micro grid according to one embodiment of the present invention.

FIG. 3 is a table showing an example of statistical classification standards according to the type of business in connection with FIG. 2.

### MODES OF THE INVENTION

Hereinafter, exemplary embodiments of an apparatus and method for supporting collection of demand resources among electricity consumers in a micro grid according to the present invention will be described with reference to the accompanying drawings.

It should be noted that the drawings are not to precise scale and may be exaggerated in thickness of lines or size of components for descriptive convenience and clarity only. In addition, terms described below are selected by considering functions in the embodiment and meanings may vary depending on, for example, a user or operator's intentions or customs. Therefore the meanings of terms should be interpreted on the basis of the overall context.

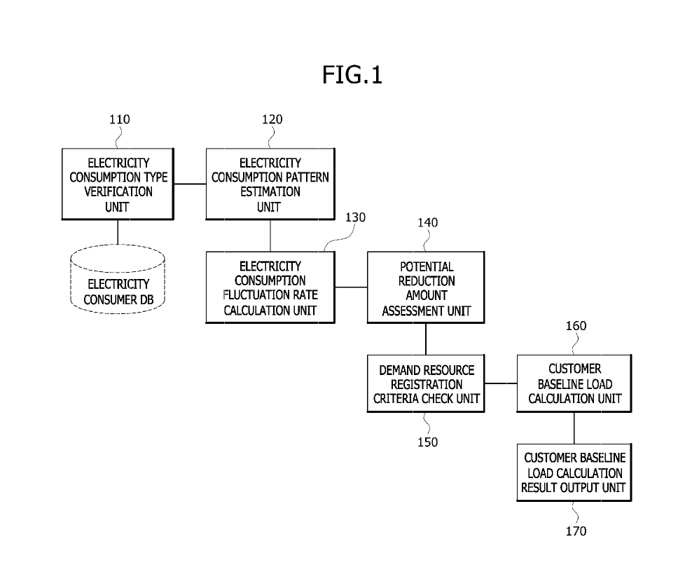

FIG. 1 is an example diagram illustrating a schematic configuration of an apparatus for supporting collection of demand resources among electricity consumers in a micro grid according to one embodiment of the present invention.

As shown in FIG. 1, the apparatus for supporting collection of demand resources among electricity consumers in a micro grid according to the present embodiment includes an electricity consumption type verification unit 110, an electricity consumption pattern estimation unit 120, an electricity consumption fluctuation rate calculation unit 130, a potential reduction amount assessment unit 140, a demand resource registration criteria check unit 150, a customer baseline load calculation unit 160, and a customer baseline load calculation result output unit 170.

In this case, it may be noted that the apparatus for supporting collection of demand resources among electricity consumers in a micro grid according to the present embodiment may use an electricity consumer database (DB), and values (e.g., hour, day, month, and the like) illustrated in the present embodiment for convenience of description may be changed to other values according to some embodiments.

First, the electricity consumption type verification unit 110 measures the accuracy of reduction assessment for a customer so as to verify whether the customer can be employed as a demand resource customer.

The electricity consumption type verification unit 110 uses a relative root mean squared error (RRMSE) to calculate an error between a customer baseline load and an actual electricity usage amount consumed during a verification target period and determines whether the customer can be employed as a demand resource customer.

Hereinafter, an example of procedures \textcircled{1} to \textcircled{6} for the electricity consumption type verification unit 100 to detect an electricity consumption type of a customer will be described.

\textcircled{1} Daily electricity usage amounts DailyUsage_{d} are calculated as shown in Formula 1 by extracting electricity usage amounts Usage_{d,t} at one hour intervals from 9:00 to 20:00 during 45 weekdays from 20 days prior to a demand resource customer registration date, which is input by a user.

$${DailyUsage}_{d} = {\sum }_{t = 9}^{t = 20} {Usage}_{d , t} , … ∀ d , ∵ 1 \leq d \leq 45 \qquad [ Formula 1 ]$$

\textcircled{2} An average daily electricity usage amount DailyAverageUsage is calculated as shown in Formula 2 by averaging the daily electricity usage amounts DailyUsage_{d}.

$$DailyAverageUsage = \frac{1}{45} \times {\sum }_{d}^{45} {DailyUsage}_{d} \qquad [ Formula 2 ]$$

\textcircled{3} For the 45 weekdays, an average daily electricity usage rate AverageRate_{d} is calculated as shown in Formula 3 below.

$${AverageRate}_{d} = \frac{\vert {DailyUsage}_{d} - DailyAverageUsage \vert}{DailyAverageUsage} … ∀ d , ∵ 1 \leq d \leq 45 \qquad [ Formula 3 ]$$

\textcircled{4} Five days are excluded from the 45 weekdays in a descending order of the average daily electricity usage rate.

\textcircled{5} Then, with respect to the remaining 40 weekdays, the customer baseline load calculation unit 160 calculates a customer baseline load CBL_{d,t} during each time period from 9:00 to 20:00 as shown in Formula 4 by using a first method (case 1: Max(4/5)) among methods of calculating a customer baseline load.

CBL_{d,t}=function_{max(4/5)}(d,t) . . . ∀d, ∵1≤d≤45, 9≤t≤20 [Formula 4]

\textcircled{6} A relative root mean squared error between the customer baseline load and the actual electricity usage amount is calculated as shown in Formula 5 below.

$$RRMSE = \sqrt{\frac{{\sum }_{d ∈ D , t ∈ T} {( {CBL}_{d , t} - {Usage}_{d , t} )}^{2}}{D ( n ) \times T ( n )}} \div \frac{{\sum }_{d ∈ D , t ∈ T} {Usage}_{d , t}}{D ( n ) \times T ( n )} \qquad [ Formula 5 ]$$

Here, D(n) denotes the number of days to be verified, T(n) denotes the number of time periods to be verified, CBL_{d,t} denotes a customer baseline load at time t on date d, and Usage_{d,t} denotes an electricity usage amount at time t on date d.

Then, the electricity consumption pattern estimation unit 120 estimates an electricity consumption pattern used by the electricity consumption fluctuation rate calculation unit 130 and the potential reduction amount assessment unit 140.

For example, the electricity consumption pattern estimation unit 120 estimates a maximum/minimum/average monthly electricity consumption pattern using weekday electricity usage amount data of the customer for the past three years.

Hereinafter, an example of procedures \textcircled{1} to \textcircled{3} for the electricity consumption pattern estimation unit 120 to estimate a customer-specific electricity consumption pattern will be described.

\textcircled{1} First, electricity usage amount data that satisfies the following conditions is extracted from the electricity usage amount data for the last three years.
Day: Monday, Tuesday, Wednesday, Thursday, and Friday
Public holiday: No
Time period: 10:00, 11:00, 12:00, 14:00, 15:00, 16:00, 17:00, 18:00, 19:00, and 20:00

\textcircled{2} A monthly electricity consumption pattern MonthlyPatten_{m,t} is estimated as shown in Formula 6 using the extracted electricity usage amount Usage_{d,t}.

$${MonthlyPattern}_{m , t} = \frac{1}{n} \times {\sum }_{d}^{n} {Usage}_{d , t} … ∀ m , t \\ ∵ d ∈ m , m ∈ last 3 years , 9 < t \leq 20 \qquad [ Formula 6 ]$$

\textcircled{3} Then, a maximum monthly electricity consumption pattern MaxMonthlyPatten_{m,t}, a minimum monthly electricity consumption pattern MinMonthlyPatten_{m,t}, and an average monthly electricity consumption pattern AvgMonthlyPatten_{m,t} are estimated as shown in Formulas 7 to 9 below.

$$\begin{matrix}{MaxMonthlyPatter}_{m} = max ( {MonthlyPattern}_{m , t} ) … ∀ m & [ Formula 7 ] \\ {MinMonthlyPatter}_{m} = min ( {MonthlyPattern}_{m , t} ) … ∀ m & [ Formula 8 ] \\ {AvgMonthlyPattern}_{m} = \frac{1}{10} {{\sum }_{t = 10}}^{20} {MonthlyPattern}_{m , t} … ∀ m & [ Formula 9 ]\end{matrix}$$

The electricity consumption fluctuation rate calculation unit 130 calculates an electricity consumption fluctuation rate of the customer using the electricity consumption pattern.

Here, the electricity consumption fluctuation rate is used as an indicator to determine the capability of implementing a demand reduction instruction. The higher the electricity consumption fluctuation rate is, the higher the rate of implementation of the demand reduction instruction is. On the other hand, when the electricity consumption fluctuation rate is low, the demand reduction instruction cannot be properly implemented and thus the customer may be charged with a penalty or be restricted in demand resource transactions.

Therefore, it is beneficial for the demand management operators (or demand resource (DR) operators) to recruit and use customers of a high electricity consumption fluctuation rate.

Hereinafter, an example of procedures \textcircled{1} to \textcircled{3} for the electricity consumption fluctuation rate calculation unit 130 to calculate an electricity consumption fluctuation rate of a customer will be described.

\textcircled{1} A monthly electricity consumption fluctuation rate Rₘ is calculated as shown in Formula 10 below.

Since the electricity consumption fluctuation rate is calculated monthly for the last three years, a total of 36 (12 months×3 years) electricity consumption fluctuation rates are calculated.

$${R}_{m} = \frac{( {MaxMonthlyPattern}_{m} - {MinMonthlyPattern}_{m } )}{{AvgMonthlyPattern}_{m}} … ∀ m , \\ ∵ m ∈ last 3 years \qquad [ Formula 10 ]$$

\textcircled{2} That is, a total of 36 values are obtained as the monthly electricity consumption fluctuation rates for 36 months.

Representative monthly consumption fluctuation rates R′ₘ are calculated by weighted averaging three values of the same months among the 36 obtained values.

For example, in the case of an electricity usage amount from 2012 to 2014, a representative electricity consumption fluctuation rate of January is calculated as shown in Formula 11 below by weighted averaging the electricity consumption fluctuation rates for the months of January 2012, January 2013, and January 2014.

$${R}_{m}^{′} = w \cdot {R}_{m}^{Y - 1} + w \cdot ( 1 - w ) \cdot {R}_{m}^{Y - 2} + w \cdot {( 1 - w )}^{2} \cdot {R}_{m}^{Y - 3} + {( 1 - w )}^{3} \cdot \frac{( {R}_{m}^{Y - 1} + {R}_{m}^{Y - 2} + {R}_{m}^{Y - 3} )}{3} \qquad [ Formula 11 ]$$

Here, a weight w applied is usually 0.2.

\textcircled{3} An electricity consumption fluctuation rate \hat{R} of a customer is finally calculated as shown in Formula 12 below by applying a weight in consideration of seasonal characteristics of each month.

$$\hat{R} = {\sum }_{m}^{12} {R}_{m}^{′} \times {α}_{m} , ∵ {\sum }_{m}^{12} {α}_{m} = 1 \qquad [ Formula 12 ]$$

The potential reduction amount assessment unit 140 assesses a potential reduction amount of the user using the electricity consumption pattern estimated by the electricity consumption pattern estimation unit 120.

Here, the potential reduction amount is used to determine how much demand a customer can reduce. The higher the potential reduction amount is, the more beneficial it is for the DR operator since the DR operator can receive a higher settlement amount even with a small number of customers. On the other hand, when the potential reduction amount is low, more customers need to be recruited and thus management cost increases, which may lead to reduction in the profit of the DR operator.

Hereinafter, an example of procedures \textcircled{1} to \textcircled{3} for the potential reduction amount assessment unit 140 to assess a potential reduction amount of a customer will be described.

\textcircled{1} A monthly potential reduction amount Aₘ that can be reduced on average for each time period in each month is calculated as shown in Formula 13 below.

In this case, since the potential reduction amount Aₘ is calculated on a monthly basis for the last three years, a total of 36 (12 months×3 years) potential reduction amounts are calculated.

$${A}_{m} = \frac{1}{n} \times {\sum }_{t}^{n} ( {MonthlyPattern}_{m , t} - {AvgMonthlyPattern}_{m} ) … ∀ m \\ ∵ m ∈ last 3 years , {MonthlyPattern}_{m , t} \geq {AvgMonthlyPatter}_{m} \qquad [ Formula 13 ]$$

\textcircled{2} That is, a total of 36 values are obtained as the monthly potential reduction amounts for 36 months.

Representative monthly potential reduction amounts A′ₘ are calculated by weighted averaging three values of the same months among the 36 obtained values.

For example, in the case of an electricity usage amount from 2012 to 2014, a representative potential reduction amount of January is calculated as shown in Formula 14 below by weighted averaging the potential reduction amounts for the months of January 2012, January 2013, and January 2014.

$${A}_{m}^{′} = w \cdot {A}_{m}^{Y - 1} + w \cdot ( 1 - w ) \cdot {A}_{m}^{Y - 2} + w \cdot {( 1 - w )}^{2} \cdot {A}_{m}^{Y - 3} + {( 1 - ω )}^{3} \cdot \frac{( {A}_{m}^{Y - 1} + {A}_{m}^{Y - 2} + {A}_{m}^{Y - 3} )}{3} \qquad [ Formula 14 ]$$

Here, a weight w applied is usually 0.2.

\textcircled{3} A potential reduction amount Â of a customer is finally calculated as shown in Formula 15 below by applying a weight in consideration of seasonal characteristics of each month.

$$\hat{A} = {\sum }_{m}^{12} {A}_{m}^{′} \times {α}_{m} , ∵ {\sum }_{m}^{12} {α}_{m} = 1 \qquad [ Formula 15 ]$$

The demand resource registration criteria check unit 150 checks whether the potential reduction amounts of customers which have been assessed by the potential reduction amount assessment unit 140 satisfy demand resource registration criteria.

Here, the demand resource registration criteria are as shown in Formula 16.

For example, the number of participating customers should be 10 (predetermined number of households) or more and the sum of potential reduction amounts of the participating customers should be greater than or equal to 10 MW and less than or equal to 500 MW.

$$C ( n ) \geq 10 and 10 MW \leq {\sum }_{c}^{n} {\hat{A}}_{c} \leq 500 MW \qquad [ Formula 16 ]$$

Here, C(n) denotes the number of customers, c denotes a customer, n denotes the number of participating customers, and Â_{c} denotes a potential reduction amount of customer c.

The customer baseline load calculation unit 160 estimates a customer baseline load calculation method to be applied for the demand resource participating customers to increase the reduction amount and thereby maximize project profitability. That is, the customer baseline load calculation unit 160 performs optimization as to which customer baseline load calculation method should be applied for the demand resource participating customers to increase the reduction amount and thereby maximize the project profitability.

In the present embodiment, the following customer baseline load calculation methods of four cases (Case 1 to Case 4) are provided.
Case 1: Max(4/5)
Case 2: Max(4/5)+SAA option
Case 3: Mid(6/10)
Case 4: Mid(6/10)+SAA option

Hereinafter, the customer baseline load calculation method of each of the four cases will be described with reference to electricity usage amount data of a customer for one year prior.

First, an example of procedures \textcircled{1} to \textcircled{3} in accordance with the method of calculating a customer baseline load in “case 1: Max(4/5)” will be described. Here, “Max(4/5)” denotes a maximum of four days (similar days) that can be extracted from the last five days (reference days) from a day d of customer baseline load calculation.

\textcircled{1} An average electricity usage amount AverageTimeUsageₜ for time periods during the last 10 weekdays from the day d of customer baseline load calculation is calculated as shown in Formula 17.

$${AverageTimeUsage}_{t} = \frac{1}{10} \times {\sum }_{k = 1}^{10} {Usage}_{d - k , t} \qquad [ Formula 17 ]$$

\textcircled{2} A maximum of four days (similar days) are extracted from the last 5 days (reference days) from the day d of customer baseline load calculation. Meanwhile, a day in which an electricity usage amount is less than 75% of average electricity usage amount is considered an abnormal working day and thus excluded from the reference days.

\textcircled{3} A customer baseline load (Formula 18) is calculated as shown in Formula 18 by averaging the electricity usage amounts for up to four days (similar days).

$${CBL}_{d , t}^{M ax ( 4 / 5 )} = \frac{1}{4} \times {\sum }_{k = 1}^{k = 4} {Usage}_{d - k , t} … , ∀ d , \\ t ∵ d ∈ similar days ( 4 days ) , 9 \leq t \leq 20 \qquad [ Formula 18 ]$$

(Customer Baseline Load)

Procedures \textcircled{1} and \textcircled{2} in accordance with a method of calculating a customer baseline load in “case 2:Max(4/5)+SAA” will be described with reference to an example.

\textcircled{1} A customer baseline load is calculated using the same method as Max(4/5).

\textcircled{2} In order to reflect an electricity usage type according to a temperature error between a similar day and a day d of customer baseline load calculation or the like, an average electricity usage amount for three hours, from four hours before a specific time of the day of interest to one hour before the specific time, is obtained and a value SAAd,t is calculated by subtracting an average electricity usage amount for the same time period of the similar day from the obtained average electricity usage amount of the day of customer baseline load calculation and is added to the previously calculated customer baseline load, thereby obtaining an adjusted customer baseline load as shown in Formulas 19 and 20.

$${adjCBL}_{d , t}^{Ma x ( 4 / 5 )} = {CBL}_{d , t}^{Ma x ( 4 / 5 )} + {SAA}_{d , t}^{Ma x ( 4 / 5 )} \qquad [ Formula 19 ]$$

(Adjusted Customer Baseline Load)

$${SAA}_{d , t}^{M ax ( 4 / 5 )} = \frac{1}{3} \times {\sum }_{l = 2}^{l = 4} {Usage}_{d , t - l} - \frac{1}{4} \times {\sum }_{k = 1}^{k = 4} ( \frac{1}{3} \times {\sum }_{l = 2}^{l = 4} {Usage}_{d - k , t - l} ) , … ∀ d , t ∵ 9 \leq t \leq 20 \qquad [ Formula 20 ]$$

An example of procedures \textcircled{1} to \textcircled{3} in accordance with a method of calculating a customer baseline load in “Case 3: Mid(6/10)” will be described.

\textcircled{1} An average electricity usage amount for time periods during the past 20 weekdays from the day d of customer baseline load calculation is calculated as shown in Formula 21 below.

$${AverageTimeUsage}_{t} = \frac{1}{20} \times {\sum }_{k = 1}^{20} {Usage}_{d - k , t} \qquad [ Formula 21 ]$$

\textcircled{2} Six days (similar days) are extracted from the last ten days (reference days) from the day d of customer baseline load calculation, excluding two days of the maximum electricity usage amount and two days of the minimum electricity usage amount. Meanwhile, a day in which an electricity usage amount is less than 75% of the average electricity usage amount is considered an abnormal working day and thus excluded from the reference days.

\textcircled{3} A customer baseline load is calculated as shown in Formula 22 below by averaging the electricity usage amounts for the six days (similar days).

$${CBL}_{d , t}^{Ma x ( 6 / 10 )} = \frac{1}{6} \times {\sum }_{k = 1}^{k = 4} {Usage}_{d - k , t} … , ∀ d , \\ t ∵ d ∈ similar days ( 6 days ) , 9 \leq t \leq 20 \qquad [ Formula 22 ]$$

(Customer Baseline Load)

An example of procedures \textcircled{1} and \textcircled{2} in accordance with a method of calculating a customer baseline load in “Case 4: Mid(6/10)+SAA” will be described.

\textcircled{1} A customer baseline load is calculated in the same method as Mid(6/10).

\textcircled{2} In order to reflect an electricity usage type according to a temperature error between a similar day and a day d of customer baseline load calculation or the like, an average electricity usage amount for three hours, from four hours before a specific time of the day of customer baseline load calculation to one hour before the specific time, is obtained and a value SAAd,t is calculated by subtracting an average electricity usage amount for the same time period of the similar day from the obtained average electricity usage amount of the day of customer baseline load calculation and added to the previously calculated customer baseline load, thereby obtaining an adjusted customer baseline load as shown in Formulas 23 and 24.

adjCBL_{d,t}^{Max(6/10)}=CBL_{d,t}^{Max(6/10)}+SAA_{d,t}^{Max(6/10)} [Formula 23]

(Adjusted Customer Baseline Load)

$${SAA}_{d , t}^{ Ma x ( 6 / 10 )} = \frac{1}{3} \times {\sum }_{l = 2}^{l = 4} {Usage}_{d , t - l} - \frac{1}{6} \times {\sum }_{k = 1}^{k = 4} ( \frac{1}{3} \times {\sum }_{l = 2}^{l = 4} {Usage}_{d - k , t - l} ) , … ∀ d , t ∵ 9 \leq t \leq 20 \qquad [ Formula 24 ]$$

The customer baseline load calculation result output unit 170 outputs a result of the calculation by the customer baseline load calculation unit 160 by including a chart (graph) and a details table therein.

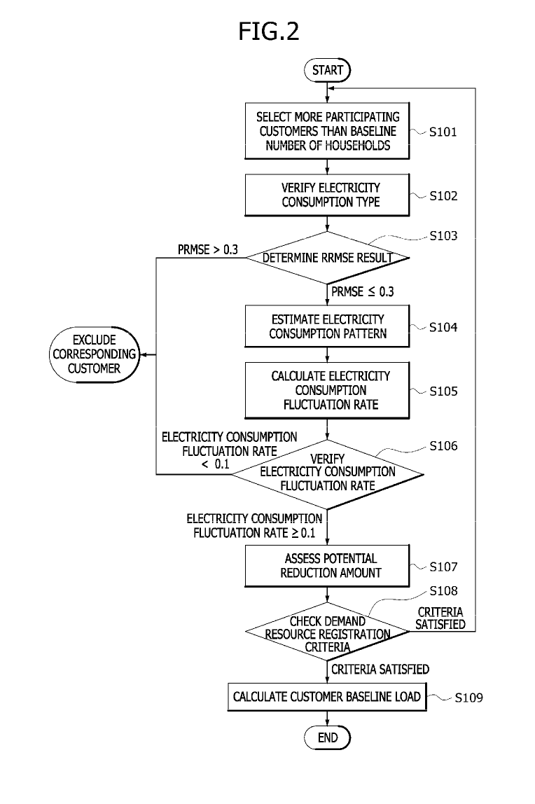

FIG. 2 is a flowchart for describing a method of supporting collection of demand resources among electricity consumers in a micro grid according to one embodiment of the present invention.

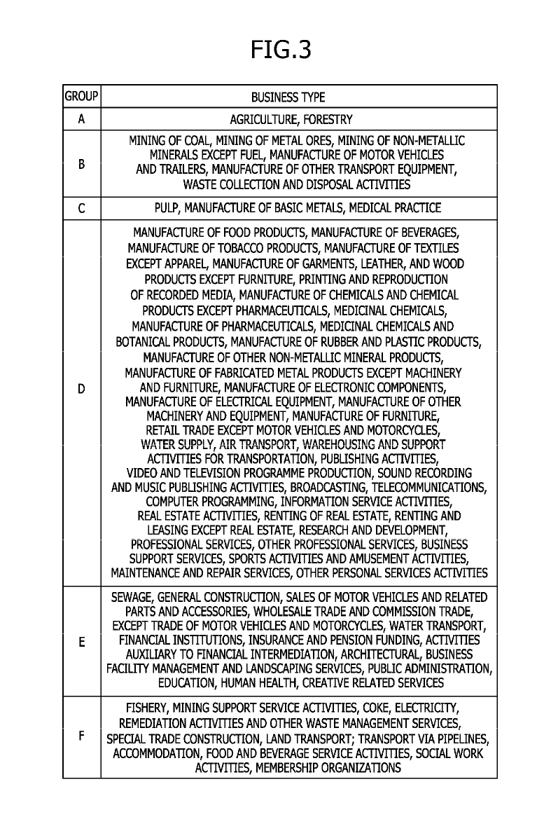

As shown in FIG. 2, the electricity consumption type verification unit 110 selects ten (preset number of households) or more participating customers with reference to electricity consumption type verification statistical data (see FIG. 3) according to a type of business, a contract type, contracted electricity, and a region (S101) and verifies electricity consumption types for the selected participating customers (S102).

That is, in order to verify the electricity consumption types for the selected participating customers, an RRMSE is calculated to obtain an error between a customer baseline load and an actual electricity usage amount consumed during a verification target period.

The electricity consumption type verification unit 110 may determine, on the basis of the RRMSE result, whether the selected customer is employable as a demand resource customer.

For example, a customer with an RRMSE greater than 0.3, which is a result of the electricity consumption type verification, is excluded from the demand resource customers and a subsequent procedure is performed (S103). Customers with an RRMSE that is greater than 0.3 are not allowed to participate in a demand resource market.

Then, the electricity consumption pattern estimation unit 120 estimates an electricity consumption pattern for the customers who have passed the electricity consumption type verification (S104) and calculates an electricity consumption fluctuation rate (S105).

For example, a customer with an electricity consumption fluctuation rate less than 0.1 is excluded from the selected customers and a subsequent procedure is performed (S106). This is because a customer with a high electricity consumption fluctuation rate has high variability in electricity consumption pattern and thus, when participating in a demand management program, the customer may be considered to have enough ability to reduce demand.

The potential reduction amount assessment unit 140 assesses a potential reduction amount for the customers who have passed the calculation of electricity consumption fluctuation rate (S107).

Then, the demand resource registration criteria check unit 150 checks whether the number of participating customers is ten (predetermined number of households) or more according to demand resource registration criteria and whether the sum of potential reduction amounts of the participating customers meets a requirement for a demand resource reduction amount (e.g., 10 MW≤reduction amount≤500 MW) (S108).

When the demand resource registration criteria are not satisfied, the process returns to the first procedure, and when the demand resource registration criteria are satisfied, a customer baseline load that maximizes a reduction amount of the customer (i.e., maximizes profitability) is selected using one of four methods of calculating a customer baseline load which can be selected for each customer when a demand resource is configured (S109).

FIG. 3 is a table showing an example of statistical classification standards according to the type of business in connection with FIG. 2. As shown in FIG. 3, statistical classification standards according to the type of business are provided by classifying statistical data on the basis of types of business from group A to group F.

For reference, statistical classification standards according to a contract type are based on a type of contract that a customer makes with a business operator (e.g., Korea Electric Power Corporation (KEPCO)), statistical classification standards according to contracted electricity are based on contracted electricity for which a customer makes a contract with a business operator (e.g., KEPCO), and statistical classification standards according to a region are based on an administrative district.

The present embodiment as described above enables high quality demand resources to be discovered from among electricity consumers belonging to a micro grid and to participate in a demand resource market. In addition, through demand management in a demand resource market, it is possible to avoid construction costs for liquefied natural gas (LNG) and oil power plants operated as reserve capacity for use during power peaks, such as winter and summer days, thereby reducing the social costs.

While the present invention has been particularly shown and described with reference to the exemplary embodiments thereof, it will be understood by those of ordinary skill in the art that various changes in form and details may be made therein without departing from the spirit and scope of the present invention as defined by the following claims.

1. An apparatus for supporting collection of demand resources among electricity consumers in a micro grid, the apparatus comprising:
an electricity consumption type verification unit configured to measure an accuracy of reduction amount assessment for a customer, who participates as a demand resource among electricity consumers, to thereby verify whether the customer is employable as a demand resource customer;
an electricity consumption pattern estimation unit configured to estimate an electricity consumption pattern of the customer;
an electricity consumption fluctuation rate calculating unit configured to calculate an electricity consumption fluctuation rate of the customer using the electricity consumption pattern;
a potential reduction amount assessment unit configured to a potential reduction amount of the customer using the electricity consumption pattern;
a demand resource registration criteria check unit configured to check whether the sum of potential reduction amounts of the customers for whom the assessment is completed by the potential reduction amount assessment unit satisfies demand resource registration criteria;
a customer baseline load calculation unit configured to calculate, for the customers satisfying the demand resource registration criteria, customer baseline loads by project profitability is maximized; and
a customer baseline load calculation result output unit configured to output a result of the calculation by the customer baseline load calculation unit using a chart and a details table.

2. The apparatus of claim 1, wherein the electricity consumption type verification unit calculates an error between a customer baseline load and an actual electricity usage amount consumed during a verification target period by using a relative root mean squared error (RRMSE) technique so as to determine, on the basis of an RRMSE result, whether the customer is employable as a demand resource customer.

3. The apparatus of claim 2, wherein the electricity consumption type verification unit is configured to:
calculate daily electricity usage amounts by extracting electricity usage amounts at predetermined time intervals during a predetermined time period for a predetermined number of weekdays from predetermined days prior to a demand resource customer registration date input by a user;
calculate an average daily electricity usage amount by averaging the daily electricity usage amounts;
calculate daily electricity usage rates for the predetermined number of weekdays;
exclude a predetermined number of days in a descending order of the average daily electricity usage rate;
calculate, for the remaining weekdays after excluding the predetermined number of days from the predetermined number of weekdays, customer baseline loads at each time period during a predetermined period of time; and
calculate the RRMSE between the customer baseline load and the actual electricity usage amount.

4. The apparatus of claim 1, wherein the electricity consumption pattern estimation unit estimates maximum/minimum/average monthly electricity consumption patterns of the customer using customer's weekday electricity usage amount data for the last predetermined number of years.

5. The apparatus of claim 4, wherein the electricity consumption pattern estimation unit is configured to:
extract, from electricity usage amount data for the last predetermined number of years, electricity usage amount data at predetermined time intervals for a predetermined number of weekdays;
calculate monthly electricity consumption patterns using the extracted electricity usage amount data; and
estimate a maximum monthly electricity consumption pattern, a minimum monthly electricity consumption pattern, and an average monthly electricity consumption pattern from the calculated monthly electricity consumption patterns.

6. The apparatus of claim 1, wherein the electricity consumption fluctuation rate calculation unit is configured to:
calculate monthly electricity consumption fluctuation rates for the last predetermined number of years;
calculate representative monthly electricity consumption fluctuation rates by weighted averaging every three monthly electricity consumption fluctuation rates of the same month; and
finally calculate the customer's electricity consumption fluctuation rate by applying a weight in consideration of seasonal characteristics of each month.

7. The apparatus of claim 1, wherein the potential reduction amount assessment unit is configured to:
calculate monthly potential reduction amount which is savable on average for each time period in each month for the last predetermined number of years;
calculate representative monthly potential reduction amount by weighted averaging values of every three monthly potential reduction amounts of the same month; and
finally calculate the customer's potential reduction amount by applying a weight in consideration of seasonal characteristics of each month.

8. The apparatus of claim 1, wherein the demand resource registration criteria includes:
the number of demand resource customers that is greater than or equal to a predetermined number of households; and
the sum of potential reduction amounts of demand resource customers that is greater than or equal to several tens of megawatts and less than or equal to several hundreds of megawatts.

9. The apparatus of claim 1, wherein the customer baseline load calculation unit provides customer baseline load calculation methods for at least four cases (Case 1 to Case 4), and in connection with a first case (Case 1: Max(4/5)), the customer baseline load calculation unit calculates an average electricity usage amount of a time period during the last predetermined number of weekdays prior to a day of customer baseline load calculation, extracts a predetermined maximum number of similar days from the last predetermined number of reference days prior to the day of customer baseline load calculation, and calculates the customer baseline load by averaging electricity usage amounts of the predetermined maximum number of similar days.

10. The apparatus of claim 9, wherein in connection with a second case (Case 2: Max((4/5)+SAA) among the four cases, the customer baseline load calculation unit calculates a customer baseline load in the same method as the first case, and in order to reflect an electricity usage type according to a temperature error between a similar day and the day of customer baseline load calculation, the customer baseline load calculation unit obtains an average electricity usage amount for a predetermined period of time before a predetermined time of the day of customer baseline load calculation, subtracts an average electricity usage amount for the same period of a similar day from the obtained average electricity usage amount, and calculates an adjusted customer baseline load by adding a subtraction result to the previously calculated customer baseline load.

11. The apparatus of claim 9, wherein in connection with a third case (Case 3: Mid(6/10)) among the four cases, the customer baseline load calculation unit is configured to:
calculate an average electricity usage amount for a predetermined time period during the previously predetermined number of weekdays prior to the day of customer baseline load calculation;
extract similar days from the predetermined number of reference days prior to the day of customer baseline load calculation, excluding days with a maximum electricity usage amount and days with a minimum electricity usage amount; and
calculate the customer baseline load by averaging electricity usage amounts of the similar days.

12. The apparatus of claim 11, wherein in connection with a fourth case (Case 4: Mid(6/10)+SAA) among the four cases, the customer baseline load calculation unit calculates a customer baseline load in the same method as the third case, and in order to reflect an electricity usage type according to a temperature error between a similar day and the day of customer baseline load calculation, the customer baseline load calculation unit obtains an average electricity usage amount for a predetermined period of time before a predetermined time of the day of customer baseline load calculation, subtracts an average electricity usage amount for the same period of a similar day from the obtained average electricity usage amount, and calculates an adjusted customer baseline load by adding a subtraction result to the previously calculated customer baseline load.

13. A method of supporting collection of demand resources among electricity consumers in a micro grid, the method comprising:
selecting, by an electricity consumption type verification unit, a number of demand resource participating customers that are greater than or equal to a predetermined number of households and verifying electricity consumption types for the selected participating customers;
calculating, by an electricity consumption pattern estimation unit and an electricity consumption fluctuation rate calculation unit, electricity consumption patterns and electricity consumption fluctuation rates, respectively, for the customers who have passed the electricity consumption type verification;
assessing, by a potential reduction amount assessment unit, potential reduction amounts for the customers who have passed the electricity consumption fluctuation rate calculation;
checking, by a demand resource registration criteria check unit, whether the number of participating customers is greater than or equal to the predetermined number of households according to demand resource registration criteria and the sum of potential reduction amounts of participating customers satisfies a requirement for a demand reduction amount; and
calculating, by a customer baseline load calculation unit, a customer baseline load that maximizes a reduction amount of a customer using one or more customer baseline load calculation methods that is selectable for each customer satisfying the demand resource registration criteria when a demand resource is configured.

14. The method of claim 13, wherein in order to verify the electricity consumption type, the electricity consumption type verification unit is configured to:
calculate an error between a customer baseline load and an actual electricity usage amount consumed during a verification target period using a relative root mean squared error (RRMSE) technique; and
exclude a customer with an RRMSE that is greater than a predetermined baseline value from demand resource participating customers.

15. The method of claim 13, wherein, after the electricity consumption fluctuation rates are calculated, a customer with the electricity consumption fluctuation rate less than a predetermined baseline value is excluded from demand resource participating customers.

16. The method of claim 13, wherein the electricity consumption fluctuation rate is used as an indicator for determining whether a demand reduction instruction is implementable by the customer, a higher electricity consumption fluctuation rate indicates a higher rate of implementation of the demand reduction instruction, and a lower electricity consumption fluctuation rate indicates a lower rate of implementation of the demand reduction instruction.

17. The method of claim 13, wherein the potential reduction amount is used to determine how much demand is savable by the customer, more settlement amount is received with a small number of customers as the potential reduction amount is higher, and when the potential reduction amount is low, more customers need to be recruited.
